(19) United States
(12) Patent Application Publication
(10) Pub. No.: US 2026/0003293 A1
(43) Pub. Date: Jan. 1, 2026

(54) METHOD AND SYSTEM OF CORRECTING OPTICAL PROXIMITY CORRECTION (OPC) MODEL FOR MANUFACTURING SEMICONDUCTOR DEVICE

(71) Applicant: TAIWAN SEMICONDUCTOR MANUFACTURING COMPANY LTD., HSINCHU (TW)

(72) Inventors: CHIEN-JEN LAI, HSINCHU (TW); SPENSER ANDERSON, HSINCHU (TW)

(21) Appl. No.: 18/754,208

(22) Filed: Jun. 26, 2024

(51) Int. Cl. G03F 7/00

(52) U.S. Cl. CPC G03F 7/70441; G03F 7/705; G03F 7/70625

(57) ABSTRACT

A method of training model for manufacturing a semiconductor device is provided. Training image data is collected from at least two wafer images on a same wafer. A metrology error function is determined according to the contour difference between at least two wafer images. A metrology-aware correction model including an optical proximity correction (OPC) model and a metrology model is trained based on the metrology error function associated with the metrology model, to obtain a trained OPC model and a trained metrology model.

### BACKGROUND

In advanced semiconductor technologies, the continuing reduction in device size and increasingly complicated circuit arrangements have made the design and fabrication of integrated circuits (ICs) more challenging and costly. Before a circuit design for the ICs is delivered for mass production, the design must be confirmed as meeting the design specification and manufacturing criteria. In order to detect design errors or defects as early as possible, circuit designers use computer-aided circuit design tools, which have become widely accepted in the semiconductor industry, to assist in identifying potential defects. However, as circuit complexity and device density continue to increase, the software procedures involved in circuit design and verification now consume a great deal of time and resources. Therefore, it is necessary to improve the design flow for reducing design cycle time while maintaining design quality.

Light diffraction in an optical lithography operation presents one obstacle to reducing the feature size. Common techniques used to compensate for the light diffraction effect include optical proximity correction (OPC). These methods may be performed repeatedly across the design layout in order to ensure acceptable enhancement results for all patterns in the design layout. As a result, a large amount of software resources may be required, and significant cost may be incurred to perform lithography enhancement on the design layout. Design inefficiency and process cost have thus become challenges to be overcome in order to attain economical mass production of the devices. Accordingly, there is a need for a more effective lithography enhancement approach that does not compromise performance.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or decreased for clarity of discussion.

FIG. 1 is a schematic diagram showing an IC manufacturing system in accordance with some embodiments of the present disclosure.

FIG. 2 is a schematic diagram showing the mask data preparation block in the IC manufacturing system of FIG. 1, in accordance with some embodiments of the present disclosure.

FIG. 3 is a schematic diagram showing the model enhancement block in the mask data preparation block of FIG. 2, in accordance with some embodiments of the present disclosure.

FIG. 4A is a flowchart of a method 400 for training the metrology-aware correction model of FIG. 3, in accordance with some embodiments of the present disclosure.

FIG. 4B is a flowchart of the operation of training the metrology-aware correction model in FIG. 4A, in accordance with some embodiments of the present disclosure.

FIGS. 5A and 5B show a first wafer image and a second wafer image of an array of features collected on the same semiconductor wafer, respectively, in accordance with some embodiments of the present disclosure.

FIG. 6A shows a first contour and a second contour of a feature measured in different measurement settings, in accordance with some embodiments of the present disclosure.

FIG. 6B shows a curve of a contour difference between the first contour and the second contour shown in FIG. 6A, in accordance with some embodiments of the present disclosure.

FIG. 7 shows a resist image with the angle of the gradient vector, in accordance with some embodiments of the present disclosure.

FIG. 8 is a schematic diagram showing an exemplary training model for the method of FIG. 4A, in accordance with some embodiments of the present disclosure.

FIG. 9 is a flowchart of a method of manufacturing a semiconductor device, in accordance with some embodiments of the present disclosure.

FIG. 10 shows a schematic diagram showing a procedure of fabricating a semiconductor wafer based on a design layout, in accordance with some embodiments of the present disclosure.

FIG. 11 shows a performance comparison of modeling errors between the models with or without the modeling of the metrology errors, in accordance with some embodiments of the present disclosure.

FIG. 12 is a schematic diagram of a system implementing the lithography methods discussed above, in accordance with some embodiments of the present disclosure.

### DETAILED DESCRIPTION

The following disclosure provides many different embodiments, or examples, for implementing different features of the provided subject matter. Specific examples of components and arrangements are described to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

While embodiments of the present disclosure are discussed in detail, it should be appreciated that the present disclosure provides many applicable inventive concepts that can be embodied in a wide variety of specific contexts. The specific embodiments discussed are merely illustrative and do not limit the scope of the disclosure.

Further, spatially relative terms, such as “beneath”, “below”, “lower”, “above”, “upper”, “lower”, “left”, “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As will be appreciated by one skilled in the art, the embodiments of the present disclosure may be implemented as a system, method, or computer program product. Accordingly, the embodiments of the present disclosure may take the form of an embodiment included entirely of hardware, an embodiment included entirely of software (including firmware, resident software, micro-code, etc.) or an embodiment combining software and hardware aspects. The various types of embodiments mentioned may all generally be referred to herein as a “circuit”, “block”, “module” or “system”. Furthermore, the embodiments of the present disclosure may take the form of a computer program embodied in any tangible medium of expression having program codes embodied in the medium and executable by a computer.

The terms “reticle”, “photomask” and “mask” used throughout the present disclosure refer to a device used in a lithography operation, in which an opaque image according to a circuit pattern is formed on a substrate plate. The substrate plate may be transparent. The image of the circuit pattern on the reticle is transferred to a substrate or a wafer through a radiation source of the lithography operation. Radiation from the radiation source may be incident on the substrate via the reticle in a transmissive or reflective manner.

The terms “layout”, “design layout” and “mask layout” used throughout the present disclosure refer to a representation of an integrated circuit (IC) in terms of geometric patterns which correspond to the features of the IC, such as a metal layer, a dielectric layer, or a semiconductor layer, that make up the components of the IC. In some examples, the terms “layout”, “design layout” and “mask layout” refer to a data file including machine-readable codes or text strings that can be converted into the geometric patterns. Additional information, such as parameters extracted from the geometric patterns, in relation to the IC may be included in the layout or design layout for enhancing the design and manufacturing processes of the IC.

The term “exposure field” or simply “field” used throughout the present disclosure refers to an exposure area defined in a workpiece, such as a semiconductor wafer, in a photolithography (or simply lithography) operation. The fields may be arranged in an array and separated by partitioning regions, e.g., scribe lines. During a lithography operation, a predetermined circuit pattern is formed on a material layer of the workpiece by a patterning operation that includes transferring a master copy of the circuit pattern fabricated on a mask to the workpiece. The transferring of the circuit pattern is usually conducted by causing a patterned radiation beam, which follows the geometry of the circuit pattern of the mask, to irradiate the exposure fields in succession. The circuit pattern of the mask may be duplicated in each of the exposure fields.

The present disclosure relates generally to the subject of semiconductor devices and relates more particularly to a layout enhancement method for lithography enhancement under deep ultraviolet (DUV) or extreme ultraviolet (EUV) radiation. Lithography enhancement is employed for modifying patterns of a design layout such that the enhanced design layout takes into account the process factors, such as the optical effects, of the lithography operations. Moreover, the task of the lithography enhancement is more complicated for EUV lithography (EUVL) because processing factors, such as uniformity and leakage of the EUV radiation, on the exposure performance is more pronounced in EUVL than in other exposure methods that utilize greater wavelengths. Therefore, it is crucial to improve the performance of the EUVL operation.

The radiation beam, after being patterned via reflection from the mask, is radiated onto the workpiece for patterning a material layer on the workpiece. The mask is generally formed of a patterned light-reflective layer configured to reflect the radiation onto the workpiece. The mask is operated while covered by a pellicle to protect the mask from contamination. The pellicle is made substantially transparent to the radiation.

According to the embodiments of the present disclosure, a metrology model is introduced and separated from an original optical proximity correction (OPC) model during an OPC model construction process to separate the lithography effect from the metrology errors applied to a scanned circuit pattern, so that the OPC process during IC manufacturing is not affected by metrology errors. By training the OPC model and the metrology model at the same time with the metrology model incorporating a predetermined metrology error function, the metrology errors can be extracted by the metrology error function and is independent of the parameter variations of the original OPC model, thereby improving the accuracy of the OPC model. As a result, the OPC model errors occurring with the angle of contour (referred to as the contour angle) would be reduced. Furthermore, by using the de-noised OPC model, the contour of the circuit patterns (i.e., with the metrology errors removed) can be observed and scanned with greater accuracy.

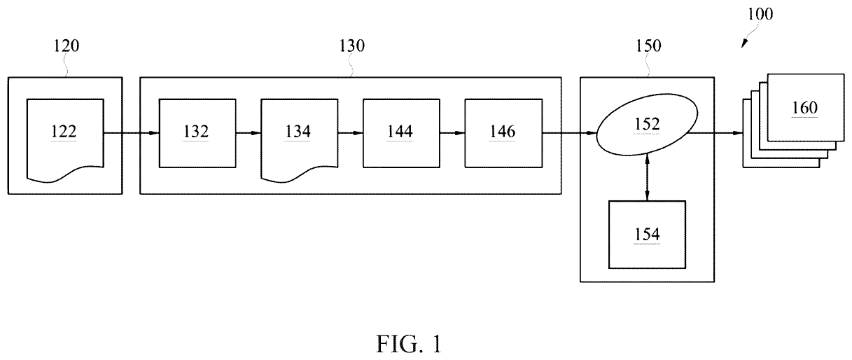

FIG. 1 is a schematic diagram showing an IC manufacturing system 100 in accordance with some embodiments of the present disclosure. The IC manufacturing system 100 is configured to manufacture an IC device 160 through a plurality of entities, such as a design house 120, a mask house 130, and an IC manufacturer (fab or foundry) 150. The entities in the IC manufacturing system 100 are linked by a communication channel, e.g., a wired or wireless channel, and interact with one another through a network, e.g., an intranet or the internet. In some embodiments, the design house 120, the mask house 130 and the IC manufacturer 150 belong to a single entity or are operated by independent parties.

The design house (or design team) 120 generates a design layout 122 in an IC design phase for the IC devices 160 to be fabricated. The design layout 122 includes descriptions of various geometrical patterns designed for performing specific functions that conform to the performance and manufacturing specifications. The geometrical patterns represent circuit features in the fabricated IC devices 160, e.g., metal layers, dielectric layers, or semiconductor layers, that form various IC components, such as an active region, a gate electrode, a source region or a drain region, and a conductive line or via of an interconnect structure (sometimes referred to as a redistribution layer). In an embodiment, the design house 120 operates a circuit design procedure to generate the design layout 122. The circuit design procedure may include, but is not limited to, logic design, physical design, pre-layout simulation, placement and routing, timing analysis, parameter extraction, design rule check and post-layout simulation. The design layout 122 may be converted from description texts into their visual equivalents to show a physical layout of the depicted patterns, such as the dimensions, shapes and locations thereof. In some embodiments, the design layout 122 can be expressed in a suitable file format such as GDSII, DFII, Oasis or the like.

The mask house 130 receives the design layout 122 from the design house 120 and manufactures one or more masks according to the design layout 122. In an embodiment, the mask house 130 includes a mask data preparation block 132, a mask fabrication block 144 and a mask inspection block 146. The mask data preparation block 132 modifies the design layout 122 so that a resulting design layout 134 can allow a mask writer to transfer the design layout 122 to a writer-readable format. Generally, the design layout 134 may include replicated cells thereon. When a mask with a mask pattern is formed, it is repeatedly used to transfer the patterns of the cells to a semiconductor wafer, wherein the pattern transfer is done with an exposure field in each shot. In addition, scribe line regions or test structures may be formed in spaces between the exposure fields. In some embodiments, the mask data preparation block 132 is configured to determine the locations of dies that are to be included in a cell, the locations and widths of scribe line regions around the cells, and the locations and types of test structures to be formed in the scribe line regions.

The mask fabrication block 144 is configured to form a mask with a mask pattern by preparing a substrate based on the design layout 134 provided by the mask data preparation block 132. A mask substrate is exposed to a radiation beam, such as an electron beam, based on the pattern of the design layout 134 in a writing operation, which may be followed by an etching operation to leave behind the patterns corresponding to the design layout. In an embodiment, the mask fabrication block 144 introduces a checking procedure to ensure that the layout data complies with requirements of a mask writer and/or a mask manufacturer and that the layout data can be used to generate the mask (photomask or reticle) as desired. An electron-beam (e-beam), multiple e-beams, an ion beam, a laser beam or other suitable writer source may be used to transfer the patterns. As a result, the patterns of the cells as acquired are transferred to a semiconductor substrate (such as a wafer) or material layers disposed on the semiconductor substrate. Moreover, the mask can be fabricated in various technologies. In an embodiment, the mask is fabricated using binary technology in which a binary mask includes a transparent substrate (e.g., fused quartz) and an opaque material (e.g., chromium) coated on the opaque regions of the mask. In another example, the mask is fabricated using a phase shift technology, e.g., a phase shift mask (PSM).

After the mask is fabricated, the mask inspection block 146 inspects the fabricated mask to determine if any defects, such as full-height and non-full-height defects, exist in the fabricated mask. If any defects are detected, the mask may be cleaned or the design layout in the mask may be modified.

The IC manufacturer 150 is an IC fabrication entity that includes multiple manufacturing facilities for the fabrication of a variety of different IC products. The IC manufacturer 150 uses the mask fabricated by the mask house 130 to fabricate a semiconductor wafer 152 having a plurality of IC devices 160 thereon. The semiconductor wafer 152 may include a silicon substrate or another suitable substrate including various layers formed thereon. In an embodiment, the IC manufacturer 150 includes a wafer testing block 154 configured to ensure that the IC conforms to physical manufacturing specifications and mechanical and/or electrical performance specifications. In some embodiments, the test structures formed on the semiconductor wafer 152 may be utilized to generate test data indicative of the quality of the semiconductor wafer 152. After the semiconductor wafer 152 passes the testing procedure performed by the wafer testing block 154, the semiconductor wafer 152 may be diced (or sliced) along the scribe line regions to form separate IC devices 160. The dicing process can be accomplished by scribing and breaking, by mechanical sawing (e.g., with a dicing saw) or by laser cutting.

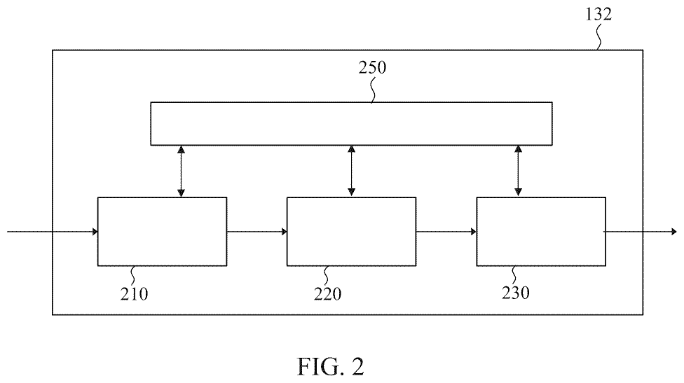

FIG. 2 is a schematic diagram showing the mask data preparation block 132 in the IC manufacturing system 100 of FIG. 1, in accordance with some embodiments of the present disclosure. The mask data preparation block 132 includes a logic operation (LOP) module 210, an optical proximity correction (OPC) module 220, and a lithography process check (LPC) module 230.

The LOP module 210 receives or defines a set of design rules representing the manufacturing constraints from various manufacturers to check the design layout 122. The design rules may include the line width requirements, spacing requirements between adjacent features, and the like. These design rules are usually implemented as logic operations. The LOP module 210 further processes the design layout 122 and modifies the design layout 122 according to specified manufacturing rules. If the features in the design layout 122 do not comply with the set of rules, the design layout 122 will be modified accordingly by the LOP module 210 until the modified design layout 122 complies with such rules. The modification of the design layout 122 performed by the LOP module 210 may include resizing, reshaping or reallocating the features of the design layout 122.

The OPC module 220 is configured to perform a rule-based or model-based modification to the design layout 122. The design layout 122 is revised or adjusted according to predetermined correction rules and models, e.g., OPC models. For example, the OPC module 220 is configured to apply a model-based lithography enhancement technique to compensate for imaging errors, such as diffraction, interference, or other effects arising from the lithography process. In some embodiments, the OPC module 220 takes into account the flare effect or slit effect of lithography operations resulting from the defects of the optical elements in a lithography system. In some embodiments, the OPC module 220 is aimed at generating a target pattern of the design layout 122, in which the target pattern conforms to requirements of the electrical and physical functionalities sought by the design layout 122 despite the geometric differences between the design layout 122 and the target pattern. The target pattern is also used as a reference in determining differences between the desired circuit pattern and a simulated manufactured pattern.

The LPC module 230 is configured to simulate the fabrication procedure that is to be implemented by the IC manufacturer 150. The simulation may cover the entirety or a portion of the design layout 122. In the present embodiment, the LPC module 230 simulates the design layout 122 undergoing the procedures of the LOP module 210 and the OPC module 220. In some embodiments, the LPC module 230 is configured to inspect the design layout 122 and detect any potential problematic areas, known as “hot spots,” that may appear in the IC device 160. The term “hot spot” refers to a feature in the IC device 160 that exhibits characteristics negatively affecting the performance of the device. A hot spot can arise from the circuit design and/or process controls. Symptoms of hot spots include pinching/necking, bridging, dishing, erosion, resistance-capacitance (RC) delay, line thickness variations and other problems.

The mask data preparation block 132 further includes a model enhancement block (or module) 250. The model enhancement block 250 is capable of training the models used in the LOP module 210, the OPC module 220, and the LPC module 230 before receiving the design layout 122 from the design house 120. In some embodiments, the parameters in the OPC module 220, may be trained using previously-collected images of the semiconductor wafer 152, and/or trained through a design layout, e.g., from the historical enhancement results of the OPC module 220 associated with other pieces of layout data.

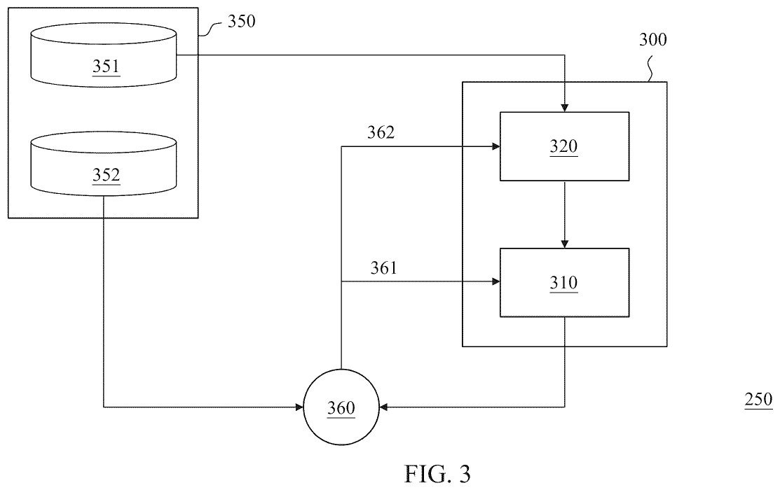

FIG. 3 is a schematic diagram showing the model enhancement block 250 in the mask data preparation block 132 of FIG. 2, in accordance with some embodiments of the present disclosure. In the embodiment of FIG. 3, the model enhancement block 250 is capable of training a metrology-aware correction model 300 of the OPC module 220 based on the previously-collected images of the semiconductor wafers 152. The previously-collected wafer images 352 along with the corresponding mask layouts 351 are stored as training image data 350. The training image data 350 is used to train an OPC model 320 and a metrology model 310 of the metrology-aware correction model 300 formed, so as to remove the impact of metrology errors in OPC operations of the OPC module 220. In other words, for manufacturing a mask with a mask pattern, the metrology model 310 accounts for a metrology error of the wafer image of the mask pattern, and the OPC model 320 accounts for optical proximity effect of the wafer image of the mask pattern.

The OPC model 320 and the metrology model 310 are arranged and trained with a cascaded approach. In some embodiments, the mask layouts 351 from the training image data 350 are used as the training input for training the OPC model 320 and the metrology model 310. Furthermore, the predictions generated by the OPC model 320 are successively fed into the metrology model 310 cascaded to the OPC model 320, and the predictions generated by the metrology model 310 and the corresponding wafer images 352 from the training image data 350 are provided to the optimizer 360 to generate the feedback signal 362 and the feedback signal 361 for the OPC model 320 and the metrology model 310, respectively. During the training process, the parameters of the OPC model 320 as well as those of the metrology model 310 are tuned based on the feedback signals 362 and 361 respectively with more input training data from the training image data 350. In some embodiments, the feedback signals 362 and 361 are generated in an alternating way to tune the parameters of the OPC model 320 and the metrology model 310 in turn until the parameters of the OPC model 320 and the metrology model 310 attains convergence. In some other embodiments, the feedback signals 362 and 361 are provided to the OPC model 320 and the metrology model 310 respectively and simultaneously to tune the parameters of the OPC model 320 and the metrology model 310 at the same time. This cascading arrangement can be an effective way to improve the overall performance for both the OPC model 320 and the metrology model 310.

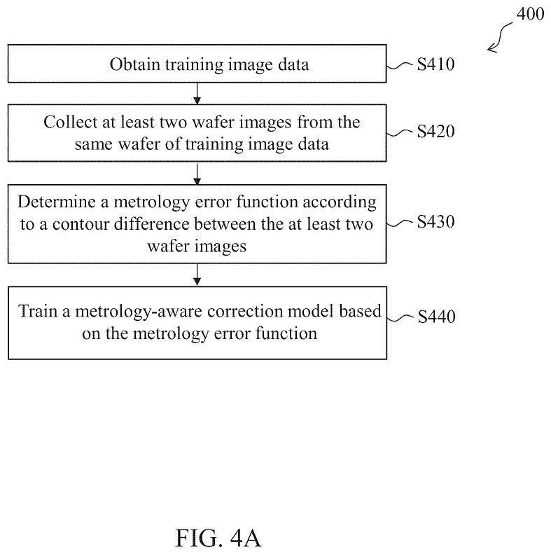

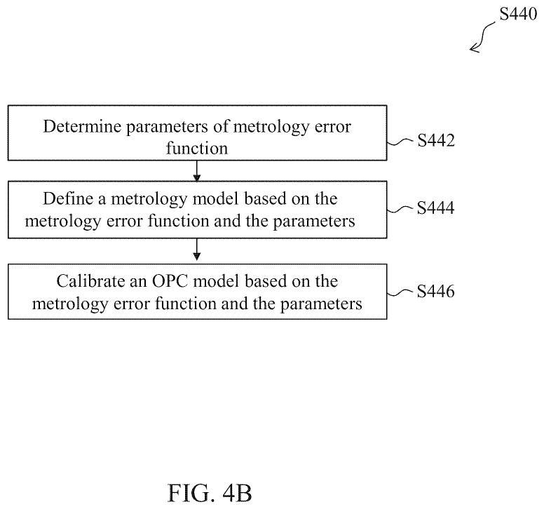

FIG. 4A is a flowchart of a method 400 for training the metrology-aware correction model 300 of FIG. 3, in accordance with some embodiments of the present disclosure. It is understood that additional operations can be provided before, during, and after the operations shown by FIG. 4A, and some of the operations described below can be replaced or eliminated, for additional embodiments of the method 400. The order of the operations may be interchangeable.

In operation S410, one or more of the semiconductor wafers 152 are measured by an image measurement system, e.g., a scanning electron microscope (SEM) to generate multiple wafer images, and the wafer images along with the corresponding mask layouts are stored in database as the mask layouts 351 and the wafer images 352 of the training image data 350. In some embodiments, the training images include one or more specific features on the semiconductor wafers 152. In some embodiments, the training images corresponding to the same specific feature are obtained from the same semiconductor wafer 152 under different measurement conditions. For example, the semiconductor wafer 152 is moved or rotated so that the specific feature can be measured from different scanning angles or directions. In some embodiments, the SEM is moved or rotated so that the specific feature can be measured from different scanning angles or directions. In some embodiments, the specific features include corners in vias, contacts or line ends, in which these corners are features where metrology errors are more pronounced than other relatively smooth locations of the features.

In operation S420, two or more wafer images of the same semiconductor wafer 152 are collected from the training image data 350. The collected wafer images 352 include the same feature on the same semiconductor wafer 152 measured or scanned from different directions. The same feature of the at least two wafer images may have different contours due to the metrology errors. Furthermore, each contour of the same feature is obtained by measuring a dimension of the same feature in the collected wafer image.

In operation S430, a metrology error function is determined according to a contour difference of the same feature between the at least two wafer images collected in operation S420. In some embodiments, the metrology error function is used to simulate the metrology error caused by the metrology parameters and scan settings of the image measurement system. Therefore, when the metrology parameters and/or scan settings change, the metrology error function also changes. In some embodiments, the metrology error function is related to angle of the contours corresponding to the same feature.

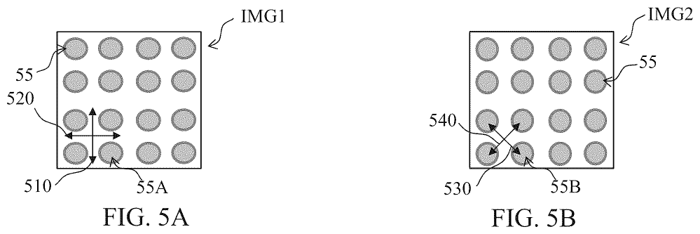

Referring to FIGS. 5A and 5B, FIGS. 5A and 5B show a first wafer image IMG1 and a second wafer image IMG2 of an array of features 55 on the same semiconductor wafer 152 that are stored as the wafer image 352 from training image data 350 and collected in operation S420 of FIG. 4A. In FIGS. 5A and 5B, the features 55 on the same semiconductor wafer 152 are the vias with the same sizes and the same shapes in layout. In some embodiments, the first wafer image IMG1 and the second wafer image IMG2 are obtained by moving or rotating the semiconductor wafer 152 or the SEM to measure the features 55 in different directions. For example, the first wafer image IMG1 of FIG. 5A is obtained by scanning the array of features 55 with a first direction 510 and a second direction 520, and the first direction 510 is perpendicular to the second direction 520. Similarly, the second wafer image IMG2 of FIG. 5B is obtained by scanning the array of features 55 with a third direction 530 and a fourth direction 540, and the third direction 530 is perpendicular to the fourth direction 540. The first direction 510 is different from the third direction 530 by substantially 45 degrees, and the second direction 520 is different from the fourth direction 540 by substantially 45 degrees.

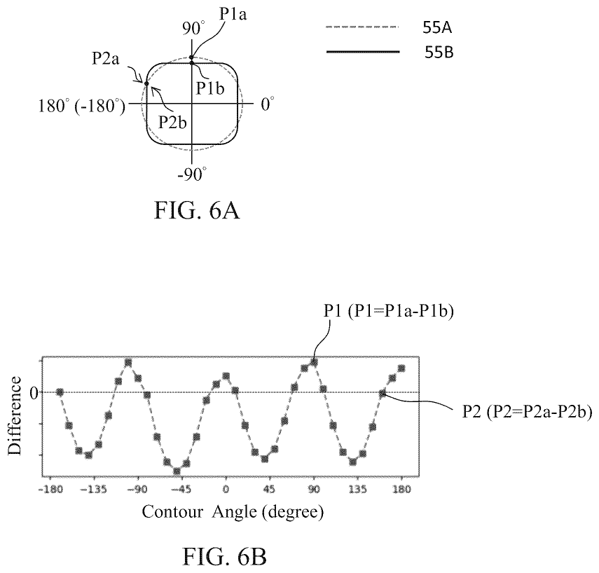

By using image processing operations, a dimension of the feature 55A in the first wafer image IMG1 and a dimension of the feature 55B in the second wafer image IMG2 are measured to respectively obtain a first contour of the feature 55A and a second contour of the feature 55B, as shown in FIG. 6A, and a curve of contour difference between the first and the second contours with respect to different contour angles is shown in FIG. 6B. In some embodiments, each of the first and the second contours is formed by connecting multiple points corresponding to the measured dimensions, in which the contour angle is the included angle measured between a reference direction, e.g., positive X-axis, and a normal to the contour, and the contour difference is measured as the gap distance between the first and the second contours along the contour angle of interest.

FIG. 6B shows the relationship between the contour angle and the contour difference between the first and the second contours. In FIG. 6B, each point represents a contour difference between the first and the second contours at a specific contour angle in FIG. 6A. For example, the point P1 at 90-degree contour angle on the first contour is greater than 0, which means that the dimension (denoted as Pla) of the first contour is greater than the dimension (denoted as P1b) of the second contour when the contour angle on the first contour is 90 degrees. Furthermore, the point P2 at 165-degree contour angle on the first contour is about equal to 0, which means that the dimension (denoted as P2a) of the first contour is equal to the dimension (denoted as P2b) of the second contour when the contour angle on the first contour is 165 degrees. By connecting the data points at different contour angles, a curve of contour difference is obtained and a metrology error function corresponding to the curve of contour difference is also obtained. Thus, it is obtained that metrology error of the contour difference varies as a function of the contour angle on the first contour. Furthermore, the metrology error in FIG. 6B shows the periodicity of the contour difference within the observation window of the contour angles from −180 degrees to +180 degrees.

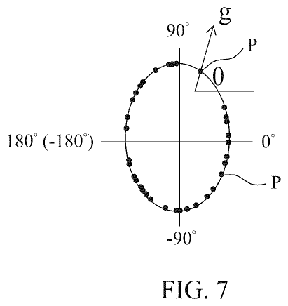

Referring back to operation S440 of FIG. 4A, the metrology-aware correction model 300 including the OPC model 320 and the metrology model 310 is trained based on the metrology error function for the metrology model 310, so as to obtain the trained OPC model 320 and the trained metrology model 310. In some embodiments, a neural network model is adopted as the OPC model 320. The metrology error function will be further described in FIG. 7 and the equations (1) through (3).

FIG. 4B is a flowchart of the operation S440 of FIG. 4A, in accordance with some embodiments of the present disclosure. It is understood that additional operations can be provided before, during, and after the operations shown by FIG. 4B, and some of the operations described below can be replaced or eliminated, for additional embodiments of the operation S440. The order of the operations may be interchangeable.

In operation S442, one or more parameters of the metrology error function are determined.

In operation S444, the metrology model 310 of the metrology-aware correction model 300 is defined based on the metrology error function and its parameters. The metrology model 310 is used to estimate the metrology errors introduced by the image measurement system.

In operation S446, the OPC model 320 is calibrated or corrected based on the metrology model, e.g., the metrology error function and its parameters, so as to remove the metrology errors. Thus, the mask fabricated by the mask house 130 is not affected by metrology-induced errors. In other words, the OPC model 320 can be considered a pure lithography model with metrology errors removed, i.e., the OPC model 320 does not require to model the metrology errors.

Through the method 400 of FIGS. 4A and 4B, the optical proximity effect and the metrology error are modeled separately. Therefore, the OPC model 320 and the metrology model 310 can be trained at the same time in a less complex manner, thereby reducing computational cost and enhancing the modelling accuracy of the optical proximity effect. Separating the optical proximity effect physics from the metrology errors leads to a simpler, more accurate OPC model 320. Furthermore, the optical proximity effect and the metrology error can be distinguished, thus obtaining an actual wafer pattern for subsequent applications.

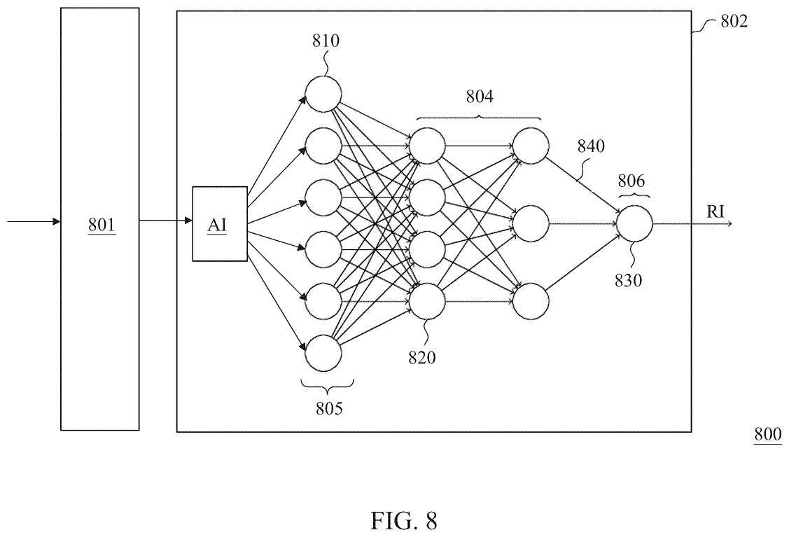

During the training operation of the metrology-aware correction model 300 in the model enhancement block 250, the OPC model 320 first computes (or generates) a data sequence Q of the optical image or so-called aerial image AI associated with the mask layouts 351 from the training image data 350 at some depth inside a photoresist of the semiconductor wafer 152 and then applies a resist image model (denoted as h_{η}, and labeled as 802 in FIG. 8) to the aerial image AI to result in a data sequence R of a transformed image called the resist image RI according to the following equation (1):

$$RI = {h}_{η} ( AI ) . \qquad ( 1 )$$

The metrology model 310 (denoted as mₚ) is sequentially applied to the resist image RI to produce a data sequence S of a metrology-based image MI according to the following equation (2):

$$MI = {m}_{p} ( RI ) . \qquad ( 2 )$$

The metrology model mₚ can alter the resist image RI with an extra term associated with the contour with respect to the corresponding contour angle θ, as shown in FIG. 7, where the contour angle θ is expressed as the angle of the gradient vector g computed by the image processing operation on the resist image RI at some data point on the contour, and the contour angle θ is in a range from −180 degrees to 180 degrees. Furthermore, the data points P on the contour corresponding to different contour angles θ are the data points where the metrology error has been calibrated with the metrology model 310. Therefore, the data sequence S of the metrology image MI can be expressed as the following equation (3):

$$MI ( n ) = RI ( n ) + {g}_{n} \cdot ( {p}_{0} + {p}_{1} cos ( K {θ}_{n} ) ) , \qquad ( 3 )$$

where “n” represents the n^{th} data point P(n), K is a constant (e.g., K=4), and the contour angle θₙ represents the contour angle θ of the data point P(n), gₙ is the gradient magnitude of RI at the data point P(n), and (p₀+p₁ cos(Kθₙ)) is referred to as the metrology error function for the metrology model 310. The metrology parameters p₀ and p₁ are the parameters to be trained in each specific batch of the training image data. For example, the metrology parameters p₀ and p₁ and the photoresist parameters n are fit together to match the training image data 350. In some embodiments, the cosine function cos (Kon) is obtained based on a specific set of metrology parameters and scan settings of the image measurement system. For example, in a four-way scanning SEM measurement process, the scanning directions comprise 510 forward, 510 backward, 520 forward, and 520 backward, and the measured contour will contain metrology error like cos (Ken). For each contour angle θₙ from −180 degrees to 180 degrees, the metrology error function computes a contour difference between the data point P(n) on the contour of the resist image RI (denoted as RI(n)) and the data point P(n) on the contour of the metrology image MI (denoted as MI(n)). According to common image processing operation, the contour difference can be converted to the image value difference between the resist image RI and the metrology image MI (i.e., the difference between the resist image RI and the metrology image MI in terms of the rectangular coordinate values (x,y)) at the data point P(n) by multiplying the magnitude of the gradient vector gₙ, which results in the term gₙ·(p₀+p₁ cos(Kθₙ)) in equation (3).

The data sequence of the measured on-wafer contour wₘₑₐₛ predicted by the metrology model mₚ, i.e., the analytical feature contour image predicted by the OPC model 320 and the metrology model 310 to emulate the metrology error-induced feature contour on the metrology image MI, is taken as the set of data points where the metrology image MI takes on a threshold value th1, as shown in the following equation (4):

$${w}_{m e a s} = \{ ( x , y ) \vert {m}_{p} ( {h}_{h} ( A I ) ) = th 1 \} , \qquad ( 4 )$$

where the values x and y represent the coordinate values of the measured on-wafer contour wₘₑₐₛ. The threshold value th1 may be set as a value between zero and one, e.g., 0.5. Therefore, the data sequence of the measured on-wafer contours wₘₑₐₛ are computed from the metrology image MI.

The data sequence of the actual on-wafer contour w_{actual} predicted by the OPC model h_{η}, i.e., the analytical on-wafer contour image predicted by the OPC model 320 to emulate the metrology error-free on-wafer contour on the resist image RI, is taken as the set of points where the resist image RI takes on a threshold value th2, as shown in the following equation (5):

$${w}_{actual} = \{ ( x , y ) \vert {h}_{h} ( A I ) = th 2 \} , \qquad ( 5 )$$

where x and y represent the coordinate value of the actual on-wafer contour w_{actual}. The threshold value th2 may be set as a value between zero and one, e.g., 0.5. In some embodiments, the threshold value th1 is equal to the threshold value th2. Therefore, the actual on-wafer contours w_{actual} with the metrology error removed can be derived from the resist image RI.

Referring to FIG. 8, FIG. 8 is a schematic diagram showing an exemplary training model 800 for the OPC model 320 in method 400 of FIGS. 4A and 4B, in accordance with some embodiments of the present disclosure. The training model 800 comprises an optical image model 801 and a resist image model 802 that has a model type of an artificial neural network constructed by a group of neurons (nodes) interconnected through the connections 840 with respective weights (parameters). The group of nodes may form various layers, e.g., an input layer 805 including one or more input nodes 810, an output layer 806 including the output node 830 and one or more hidden layers 804 including the hidden nodes 820. Hyperparameters of the resist image model 802 may also be determined, such as the number of nodes in each of the input layer 805, the output layer 806 and the hidden layers 804, and the interconnection topology of the connections 840. In some embodiments, the output layer 806 may include multiple output nodes 830. In the present embodiment, a large amount of mask layouts 351 from the training image data 350 are fed to the optical image model 801 to generate the aerial images AI that are then provided to the resist image model 802 to proceed with a machine-learning procedure. Different image features extracted from the aerial image AI are fed to input nodes 810 of the input layer 805. The output node 830 is the resist image RI without or with metrology error, depending on whether a metrology model 310 is cascaded to the OPC model 320. In some embodiments, the lithography-dependent parameters from the lithography system are also provided to the optical model 801 and/or the input layer 805 of the resist image model 802 to serve as auxiliary information for enhancing training. An iterative training process for the hidden layers 804 is performed until the values of the hidden nodes 820 attain converged values. The values of hidden nodes 820 are regarded as attaining convergence in terms of a cost function in which these converged values of the hidden nodes 820 correspond to a minimal cost value.

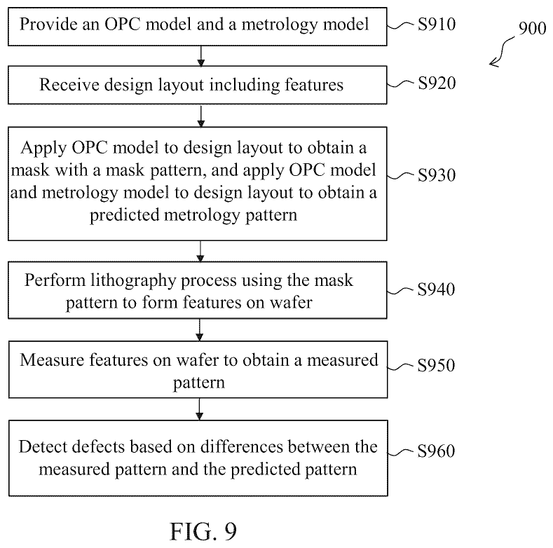

FIG. 9 is a flowchart of a method 900 of manufacturing a semiconductor device, in accordance with some embodiments of the present disclosure. It should be understood that additional operations can be provided before, during, and after the operations shown in FIG. 9, and some of the operations described below can be replaced or eliminated in other embodiments of the method 900. The order of the operations may be interchangeable.

In operation S910, a metrology-aware correction model 300 including an OPC model 320 and a metrology model 310 is provided based on a metrology error function and the training image data 350. As described above, the metrology-aware correction model 300 including the OPC model 320 and the metrology model 310 is trained based on the metrology error function, so as to remove the impact of metrology errors in OPC operations.

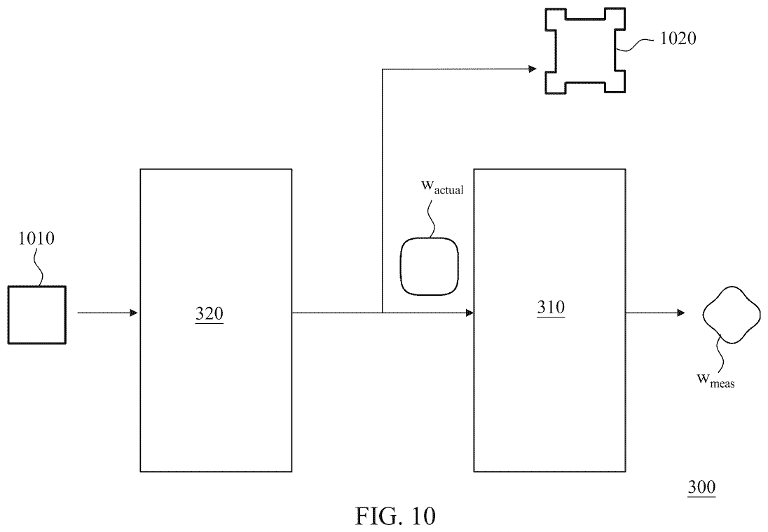

In operation S920, a design layout including one or more features is received. Each feature has a target contour in the design layout, such as a target contour 1010 of a via as shown in FIG. 10.

In operation S930, the OPC model 320 is applied to the design layout to obtain a mask (or a photomask) with a mask pattern, such as an OPC compensated design-of-mask (DOM) pattern 1020 of the via as shown in FIG. 10, and a predicted actual pattern having the actual on-wafer contour w_{actual} for the via as shown in FIG. 10. In this stage, the OPC compensated DOM pattern 1020 would not be adversely impacted by the metrology error caused by the image measurement system. Furthermore, when a predicted metrology pattern is required in subsequent procedures, the metrology model 310 is applied to the predicted actual pattern having the actual on-wafer contour w_{actual} to obtain the predicted metrology pattern having the measured on-wafer contour wₘₑₐₛ for the via as shown in FIG. 10. In other words, when the OPC model 320 and the metrology model 310 are applied to the design layout, both of the predicted actual pattern and the predicted metrology pattern can be obtained. The predicted metrology pattern may be used in the subsequent procedures to diagnose whether the features of wafer manufactured through the mask conform to the specifications of the wafer. If the predicted metrology pattern matches a measured pattern of the features from the wafer, the subsequent procedures are continued. If the predicted metrology pattern does not match the measured pattern of the features, it is determined that the defects are present in the wafer and then the wafer is to be repaired.

In operation S940, a lithography process is performed on a wafer by using the mask, so as to form the features on the wafer. As described above, the feature of the wafer has the actual on-wafer contour w_{actual} predicted by the OPC model 320, as shown in FIG. 10, and the actual on-wafer contour w_{actual} corresponds to the target contour 1010 of the design layout. In some embodiments, a photoresist layer is formed over a material layer of the wafer, and the photoresist layer is patterned by using the mask to form the features in the material layer. In some embodiments, the actual on-wafer contour w_{actual} is predicted and provided to an etching equipment for conducting etching processes on the material layer.

In operation S950, a scanning operation is performed on the wafer, so as to obtain an SEM image including a measured pattern. In some embodiments, the SEM image and the corresponding mask layout are stored in the database as the wafer image 352 and the mask layout 351 respectively in the training image data 350 to continue training the OPC model and the metrology model 310.

In operation S960, defects of the on-wafer features are detected based on contour differences between the predicted metrology pattern obtained in operation S930 and the measured feature pattern obtained in operation S950, so as to determine whether the features on the wafer manufactured through the mask conform to the specifications of the wafer. Since the metrology error has been effectively mitigated or eliminated from the actual on-wafer contour w_{actual}, the measured on-wafer contour wₘₑₐₛ can be leveraged in some scenarios to serve as the approximate version of the actual on-wafer contour w_{actual} given limited random metrology-induced noise. According to the predicted metrology pattern, the defects on the wafer can be quickly and correctly identified.

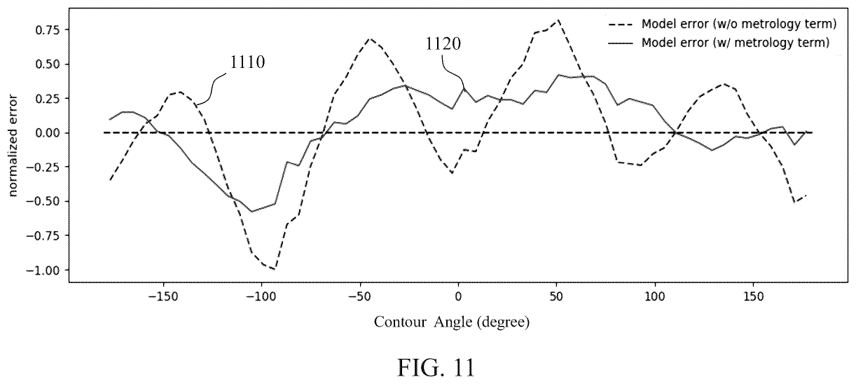

FIG. 11 shows a performance comparison of model errors between the models with or without the modeling of the metrology errors. As described above, the model error is obtained according to the contour difference between at least two contours of the same feature in different images measured with different directions. In FIG. 11, the curve 1110 represents an average error across different contour angles for an OPC model containing the metrology errors, i.e., a single model simultaneously capturing both the optical proximity effects and metrology errors. The curve 1120 represents an average error as a function of contour angle for the OPC model 320 without the metrology errors, i.e., two separate models respectively capturing the optical proximity effect and the metrology error. Compared with the curve 1110, the peaks of the curve 1120 are decreased, and the model error does not vary significantly with the contour angle (i.e., there is no periodicity) due to the presence of the metrology model 310, which is capable of capturing the equipment-induced error of the measurement system.

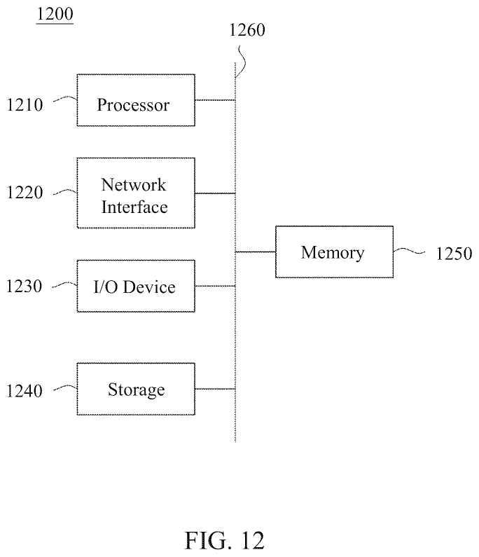

FIG. 12 is a schematic diagram of a system 1200 implementing the lithography methods discussed above, in accordance with some embodiments of the present disclosure.

The system 1200 includes a processor 1210, a network interface 1220, an input and output (I/O) device 1230, a storage device 1240, a memory 1250, and a bus 1260. The bus 1260 couples the network interface 1220, the I/O device 1230, the storage device 1240, the memory 1250 and the processor 1210 to each other.

The processor 1210 is configured to execute program instructions that include a tool configured to perform the method as described and illustrated with reference to figures of the present disclosure. Accordingly, the tool is configured to execute operations, such as performing OPC operations and so on.

The network interface 1220 is configured to access program instructions and data accessed by the program instructions stored remotely through a network (not shown).

The I/O device 1230 includes an input device and an output device configured for enabling user interaction with the system 1200. In some embodiments, the input device includes, for example, a keyboard, a mouse, and other devices. Moreover, the output device includes, for example, a display, a printer, and other devices.

The storage device 1240 is configured to store program instructions and data accessed by the program instructions. In some embodiments, the storage device 1240 includes a non-transitory computer-readable storage medium, for example, a magnetic disk and an optical disk.

The memory 1250 is configured to store program instructions to be executed by the processor 1210 and data accessed by the program instructions. In some embodiments, the memory 1250 includes any combination of a random-access memory (RAM), some other volatile storage device, a read-only memory (ROM), and some other non-volatile storage device.

According to some embodiments, a method of training model for manufacturing a semiconductor device is provided. Training image data is collected from at least two wafer images on a same wafer. A metrology error function is determined according to a contour difference between the at least two training images. A metrology-aware correction model including an optical proximity correction (OPC) model and a metrology model is trained based on the metrology error function associated with the metrology model, to obtain a trained OPC model and a trained metrology model.

According to some embodiments, a method for manufacturing a semiconductor device is provided. A metrology-aware correction model including an optical proximity correction (OPC) model and a metrology model is provided, and the metrology model is based on a metrology error function. A design layout including at least one feature is received. The metrology-aware correction model is applied to the design layout to obtain a mask pattern. A lithography process is performed using the mask pattern to form the feature on a wafer.

According to some embodiments, a system is provided. The system includes a processor and one or more programs including instructions which, when executed by the processor, cause the system to obtain training image data including a plurality of wafer images of a feature on a wafer; determine a metrology error function according to a contour difference between the plurality of training images; and train a metrology-aware correction model, including an optical proximity correction (OPC) model and a metrology model cascaded to the OPC model, based on the metrology error function to obtain a trained OPC model and a trained metrology model.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of training model for manufacturing a semiconductor device, comprising:
collecting training image data from at least two wafer images on a same wafer;
determining a metrology error function according to a contour difference between the at least two wafer images; and
training a metrology-aware correction model, including an optical proximity correction (OPC) model and a metrology model, based on the metrology error function associated with the metrology model, to obtain a trained OPC model and a trained metrology model.

2. The method of claim 1, wherein training the metrology-aware correction model further comprises:
determining at least one metrology parameter of the metrology error function according to the training image data;
defining the metrology model based on the metrology error function and the metrology parameter; and
calibrating the OPC model based on the metrology model.

3. The method of claim 1, wherein collecting the training image data further comprises:
measuring a first dimension of a first feature on a first wafer from a first wafer image of the training image data; and
measuring a second dimension of the first feature on the first wafer from a second wafer image of the training image data,
wherein the first and second wafer images are obtained by scanning the first feature on the first wafer in different directions, and the contour difference between the at least two wafer images is obtained according to the first and second dimensions.

4. The method of claim 1, further comprising:
applying the trained OPC model to a design layout to generate a mask pattern, wherein a second feature of the semiconductor device is formed on a second wafer based on the mask pattern.

5. The method of claim 4, wherein
the trained metrology model accounts for a metrology error of the wafer image of the mask pattern, and
wherein the trained OPC model accounts for an optical proximity effect of the wafer image of the mask pattern.

6. The method of claim 4, further comprising:
performing a lithography process using the mask pattern to form the second feature on the second wafer, wherein the second feature on the second wafer has a first contour corresponding to a target contour of the design layout.

7. The method of claim 6, further comprising:
applying the trained OPC model and the trained metrology model to the design layout to generate a predicted metrology pattern of the second feature to be measured from the second wafer;
measuring the second wafer to obtain a new wafer image comprising a measured pattern of the second feature on the second wafer; and
detecting defects based on differences between the measured pattern and the predicted metrology pattern.

8. The method of claim 7, further comprising:
training the OPC model and the metrology model based on the new wafer image.

9. A method for manufacturing a semiconductor device, comprising:
providing a metrology-aware correction model including an optical proximity correction (OPC) model and a metrology model wherein the metrology model is based on a metrology error function;
receiving a design layout comprising at least one feature;
applying the metrology-aware correction model to the design layout to obtain a mask pattern; and
performing a lithography process using the mask pattern to form the feature on a wafer.

10. The method of claim 9, wherein providing the metrology-aware correction model further comprises:
collecting at least two wafer images from a same wafer of training image data;
determining the metrology error function according to a contour difference between the at least two wafer images; and
training the OPC model and the metrology model, based on the metrology error function.

11. The method of claim 10, wherein training the metrology-aware correction model further comprises:
determining at least one metrology parameter of the metrology error function according to the training image data;
defining the metrology model based on the metrology error function and the metrology parameter; and
calibrating the OPC model based on the metrology model.

12. The method of claim 10, wherein collecting the at least two wafer images from the same wafer of the training image data further comprises:
measuring a first dimension of a first feature on a wafer from a first wafer image of the training image data; and
measuring a second dimension of the first feature on the wafer from a second wafer image of the training image data,
wherein the first and second wafer images are obtained by scanning the first feature in different directions, and the contour difference between the at least two wafer images is obtained according to the first and second dimensions.

13. The method of claim 10, wherein
the contour difference associated with the metrology error function includes a periodicity in a range of a contour angle between −180 degrees and +180 degrees.

14. A system, comprising a processor and one or more programs including instructions which, when executed by the processor, cause the system to:
obtain training image data including a plurality of wafer images of a feature on a wafer;
determine a metrology error function according to a contour difference between the plurality of wafer images; and
train a metrology-aware correction model, including an optical proximity correction (OPC) model and a metrology model cascaded to the OPC model, based on the metrology error function to obtain a trained OPC model and a trained metrology model.

15. The system of claim 14, wherein the instructions to train the metrology error correction model comprise instructions that, when executed by the processor, cause the system to:
determine at least one metrology parameter of the metrology error function according to the training image data;
define the metrology model based on the metrology error function and the metrology parameter; and
calibrate the OPC model based on the metrology model.

16. The system of claim 14, wherein the instructions to obtain the training image data comprise instructions that, when executed by the processor, cause the system to:
measure a first dimension of a first feature on a first wafer from a first wafer image of the training image data; and
measure a second dimension of the first feature on the first wafer from a second wafer image of the training image data,
wherein the first and second wafer images are obtained by scanning the first feature on the first wafer in different directions, and the contour difference between the wafer images is obtained according to the first and second dimensions.

17. The system of claim 14, wherein the instructions, when executed by the processor, further cause the system to:
apply the trained OPC model to a design layout to generate a mask pattern, wherein a feature is formed on a second wafer based on the mask pattern.

18. The system of claim 17, wherein
the trained metrology model accounts for a metrology error of the wafer image of the mask pattern, and
wherein the trained OPC model accounts for an optical proximity effect of the wafer image of the mask pattern.

19. The system of claim 17, wherein the instructions, when executed by the processor, further cause the system to:
apply the trained OPC model and the trained metrology model to the design layout to generate a predicted metrology pattern of the feature to be measured from the second wafer.

20. The system of claim 17, wherein the instructions, when executed by the processor, further cause the system to:
train the OPC model and the metrology model based on a wafer image from the second wafer.
